(19) United States
(12) Patent Application Publication
(10) Pub. No.: US 2025/0311194 A1
(43) Pub. Date: Oct. 2, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Wei Liu, Wuhan (CN); Dongxue Zhao, Wuhan (CN); Zhiliang Xia, Wuhan (CN); Changzhi Sun, Wuhan (CN); Di Wang, Wuhan (CN); Wenxi Zhou, Wuhan (CN)

(21) Appl. No.: 18/659,488

(22) Filed: May 9, 2024

Related U.S. Application Data
(63) Continuation of application No. PCT/CN2024/084113, filed on Mar. 27, 2024.

(51) Int. Cl. H10B 12/00; H01L 29/06; H01L 29/66; H01L 29/778

(52) U.S. Cl. CPC H10B 12/33; H10B 12/036; H10D 1/696; H10D 30/025; H10D 30/477; H10D 62/102

(57) ABSTRACT

Semiconductor devices and fabricating methods thereof are provided. The semiconductor device includes vertical transistors each including a semiconductor layer and a gate structure coupled to the semiconductor layer and cup-shaped capacitors coupled with the vertical transistors correspondingly. The semiconductor layer of each vertical transistor includes a vertical portion extending in a vertical direction and a lateral portion extending from a first end of the vertical portion in a lateral direction. The first lateral portions of the semiconductor layers of two adjacent vertical transistors in the lateral direction are connected with each other.

### CROSS-REFERENCE TO RELATED APPLICATIONS

The present application claims the benefit of priority to International Application No. PCT/CN2024/084113, filed on Mar. 27, 2024, which is hereby incorporated by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In an aspect of the present disclosure, a semiconductor device is provided. The semiconductor device includes vertical transistors each including a semiconductor layer and a gate structure coupled to the semiconductor layer and cup-shaped capacitors coupled with the vertical transistors correspondingly. The semiconductor layer of each vertical transistor includes a vertical portion extending in a vertical direction and a lateral portion extending from a first end of the vertical portion in a lateral direction. The first lateral portions of the semiconductor layers of two adjacent vertical transistors in the lateral direction are connected with each other.

In some implementations, the two adjacent vertical transistors in the lateral direction are separated by an isolation structure, and the vertical portion of each semiconductor layer is positioned between the isolation structure and the gate structure.

In some implementations, the cup-shaped capacitor includes a first electrode, a second electrode, and a dielectric layer between the first electrode and the second electrode. The first electrode is directly coupled with the semiconductor layer of the corresponding vertical transistor.

In some implementations, the second electrode includes a multiple-layer structure, each layer of the multiple-layer structure including one of TiN, TaN, carbon, polysilicon, metal, metal compounds, and silicide.

In some implementations, the cup-shaped capacitor further includes a second dielectric layer surrounding the second electrode and third electrode surrounding the second dielectric layer.

In some implementations, a material of the second dielectric layer is different from a material of the first dielectric layer.

In some implementations, the material of the second dielectric layer includes one or a combination of silicon oxide, silicon nitride, silicon oxynitride, or high-k dielectrics.

In some implementations, the first electrode is directly coupled with a second end of the vertical portion of the semiconductor layer of the corresponding vertical transistor.

In some implementations, the first electrode is coupled with the semiconductor layer of the corresponding vertical transistor through a contact, and an end of the second electrode coupled with the contact is recessed to accommodate the contact.

In some implementations, the semiconductor layer having a leakage value lower than a pico-ampere.

In some implementations, the metal oxide semiconductor includes one or a combination of InₓGa_{y}ZnₓO, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In some implementations, the semiconductor device further includes a peripheral circuit stacked on the vertical transistors.

In some implementations, the semiconductor device further includes a pad-out interconnect layer stacked on the cup-shaped capacitors.

In another aspect of the present disclosure, a method for forming a semiconductor device is provided. The method includes forming a cup-shaped capacitor and forming a vertical transistor coupled with the second electrode of the cup-shaped capacitor. Forming a cup-shaped capacitor includes forming a cell hole on an isolation layer; forming a second electrode of a capacitor in the cell hole, the cell hole is partly filled by the second electrode; forming a first dielectric layer of the capacitor on the second electrode, the cell hole is partly filled by the second electrode and the first dielectric layer; and forming a first electrode of the capacitor on the first dielectric layer to fill the cell hole.

In some implementations, forming the sup-shaped capacitor further includes removing the dielectric substrate to expose the second electrode.

In some implementations, forming the sup-shaped capacitor further includes forming a multiple-layer structure covering the exposed second electrode, and each layer of the multiple-layer structure including one of TiN, TaN, carbon, polysilicon, metal, metal compounds, and silicide.

In some implementations, forming the sup-shaped capacitor further includes forming a second dielectric layer on the exposed second electrode and forming a third electrode on the second dielectric layer.

In some implementations, a material of the second dielectric layer is different from a material of the first dielectric layer.

In some implementations, the material of the second dielectric layer includes one or a combination of silicon oxide, silicon nitride, silicon oxynitride, or high-k dielectrics.

In some implementations, forming a vertical transistor coupled with the second electrode of the cup-shaped capacitor includes forming an isolation structure, forming a semiconductor layer covering the isolation structure, and forming a gate structure coupled with the semiconductor layer. The semiconductor layers of two adjacent vertical transistors have a U-shaped cross-section in a plane formed by a vertical direction and a lateral direction.

In some implementations, the U-shaped semiconductor layer includes a vertical portion of a first vertical transistor extending in the vertical direction and a first lateral portion of the first vertical transistor extending from a first end of the vertical portion of the first vertical transistor in the lateral direction. The U-shaped semiconductor layer further includes a vertical portion of a second vertical transistor extending in the vertical direction and a first lateral portion of the second vertical transistor extending from a first end of the vertical portion of the second vertical transistor in the lateral direction.

In some implementations, before forming the vertical transistor coupled with the cup-shaped capacitor, the method further includes forming a contact between the first electrode of the capacitor and the semiconductor layer of the corresponding vertical transistor.

In some implementations, forming the vertical transistor coupled with the cup-shaped capacitor includes etching the first electrode to form a recess to accommodate the contact.

In some implementations, the method further includes forming a peripheral circuit stacked on the vertical transistors.

In some implementations, the method further includes forming a pad-out interconnect layer stacked on the cup-shaped capacitors.

In some implementations, the semiconductor layer has a leakage value lower than a pico-ampere.

In some implementations, the metal oxide semiconductor includes one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In still another aspect of the present disclosure, a semiconductor device is provided. The semiconductor device includes single-gate vertical transistors and storage units coupled with the single-gate vertical transistors correspondingly is provided. Two adjacent single-gate vertical transistors in a lateral direction are separated by an isolation structure and share a U-shaped semiconductor layer covering both sides of the isolation structure in the lateral direction. A gate structure of the single-gate vertical transistor is coupled with a side of the semiconductor layer opposite to the isolation structure. Each storage unit includes cup-shaped capacitor.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells each having a vertical transistor, according to some implementations of the present disclosure.

FIG. 2A illustrates a schematic side view of a cross-section of a semiconductor device with pillar capacitors, according to some implementations of the present disclosure.

FIG. 2B illustrates a schematic side view of a cross-section of a semiconductor device with pillar capacitors, according to some implementations of the present disclosure.

FIG. 3 illustrates a cross-section of the vertical transistors and storage units of the semiconductor device, according to some implementations of the present disclosure.

FIG. 4 illustrates a flowchart of a fabricating method for forming the semiconductor device, according to some implementations of the present disclosure.

FIGS. 5A-5O each illustrates schematic views of the semiconductor device at a certain fabricating stage of the method shown in FIG. 4, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some semiconductor devices, such as dynamic radon access memory (DRAM). In a one-transistor-one-capacitor (1T1C) DRAM structure, the data is stored in the capacitors. There is a high requirement for the leakage issue of the selection transistors. Thus, it is necessary to identify alternative channel materials with lower leakage compared to using the monocrystalline silicon as the channel material. Moreover, with the continuous scaling development of DRAM, the unit size of each capacitor cell continues to decrease, and the etching aspect ratio of the capacitors increases, causing serious challenges in the fabricating processes and increased product cost.

To address one or more of the aforementioned issues, the present disclosure introduces a solution in which low-leakage materials, such as metal oxide semiconductor materials, are selected to use as the channel of the select transistors to solve the leakage problem in the scaling process of DRAM. The disclosed semiconductor devices include single-gate vertical transistors, and the shape and structure of the active area of each vertical transistor are redesigned to accommodate the low-leakage materials. The corresponding fabricating processes of the semiconductor devices are described, in which the semiconductor layers of two adjacent vertical transistors are connected. By utilizing the new channel material for the selection transistors in DRAM and the corresponding new fabrication method, the disclosed semiconductor devices can achieve high memory density with a further reduced cell size.

Consistent with the scope of the present disclosure, according to some implementations of the present disclosure, each vertical transistor includes a semiconductor layer extending in a vertical direction and a gate structure beside the semiconductor layer. In some implementations, the word lines and bit lines connected to the vertical transistors are arranged along a first lateral direction and a second lateral direction, respectively. Each semiconductor layer of vertical transistors extends along a vertical direction. By employing such an arrangement, memory area efficiency can be increased. Furthermore, the memory cell array and the peripheral circuits can be formed separately on different wafers, such that the fabricating processes of the memory cell array and the peripheral circuits do not affect each other, thereby further increasing the memory area efficiency.

Consistent with the scope of the present disclosure, according to some implementations of the present disclosure, the semiconductor layers of two adjacent vertical transistors in the lateral direction are connected with each other, thus extending the channel length of each vertical transistor. This extension helps mitigate the short channel effect resulting from the reduced feature size. Furthermore, cup-capacitors are employed in the present disclosure as they can be formed before the fabrication of the vertical transistors without mesh layers. Therefore, the fabrication difficulty and cost are significantly reduced by the application of cup-capacitors. The corresponding fabrication method is compatible with high-temperature processes, allowing the thermal budget of the fabrication process to be fully utilized.

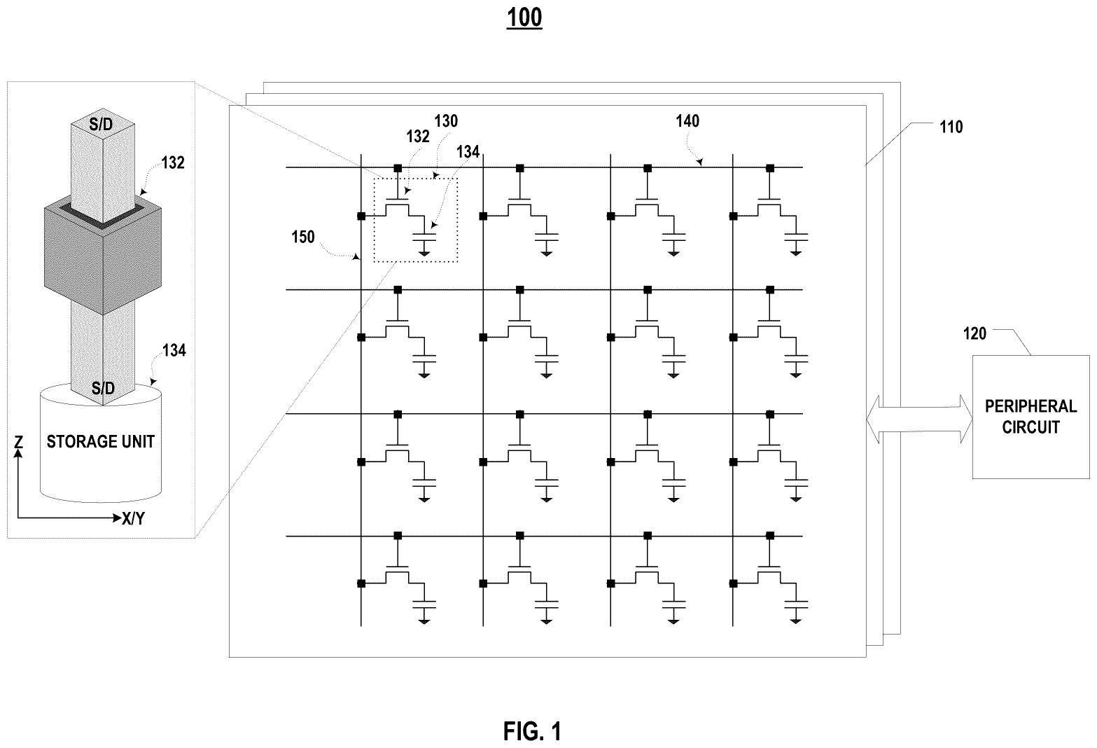

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 210 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, semiconductor body can extend above the top surface of the substrate to expose not only the top surface of semiconductor body, but also one or more side surfaces thereof. As shown in FIG. 1, for example, semiconductor body can have a cuboid shape to expose four sides thereof. It is understood that semiconductor body may have any suitable shape, such as polyhedron shapes or a cylinder shape. That is, the cross-section of semiconductor body in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor layers that have a circular or oval shape of their cross-sections in the plan view, the semiconductor layers may still be considered to have multiple sides, such that the gate structures are coupled with more than one side of the semiconductor layers. As described below with respect to the fabrication process, semiconductor body can be formed from the substrate (e.g., by etching or epitaxy) and thus, has the same semiconductor material (e.g., silicon crystalline silicon) as the substrate (e.g., a silicon substrate).

As shown in FIG. 1, vertical transistor 132 can also include a gate structure coupled with one or more sides of semiconductor body, i.e., in one or more planes of the side surface(s) of the active region. In other words, the active region of vertical transistor 132, i.e., semiconductor body, can be at least partially surrounded by gate structure. Gate structure can include a gate dielectric over one or more sides of semiconductor body, e.g., coupled with four side surfaces of semiconductor body as shown in FIG. 1. Gate structure can also include a gate electrode over and coupled with gate dielectric. Gate dielectric can include any suitable dielectric materials, such as silicon oxide, silicon nitride, silicon oxynitride, or high-k dielectrics. Gate electrode can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure in the vertical direction (the z-direction). As a result, one or more channels (not shown) of vertical transistor 132 can be formed in semiconductor body vertically between the source and drain when a gate voltage applied to gate electrode of gate structure is above the threshold voltage of vertical transistor 132.

In some implementations, as shown in FIG. 1, vertical transistor 132 is a multi-gate transistor. That is, gate structure can be coupled with more than one side of semiconductor body (e.g., four sides in FIG. 1) to form more than one gate, such that more than one channel can be formed between the source and drain in operation. That is, different from the planar transistor that includes only a single planar gate (and resulting in a single planar channel), vertical transistor 132 shown in FIG. 1 can include multiple vertical gates on multiple sides of semiconductor body due to the semiconductor structure of semiconductor body and gate structure that surrounds the multiple sides of semiconductor body. Compared with planar transistors, vertical transistor 132 shown in FIG. 1 can have a larger gate control area to achieve better channel control with a smaller subthreshold swing. During the off state, since the channel is fully depleted, the leakage current of vertical transistor 132 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 132 is shown as a multi-gate transistor in FIG. 1, the vertical transistors disclosed herein may also include single-gate transistors as described below in detail. That is, gate structure may be coupled with a single side of semiconductor body, for example, for the purpose of increasing the transistor and memory cell density. It is also understood that although gate dielectric is shown as being separate (i.e., a separate structure) from other gate dielectrics of adjacent vertical transistors (not shown), gate dielectric may be part of a continuous dielectric layer having multiple gate dielectrics of vertical transistors.

As shown in FIG. 1, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

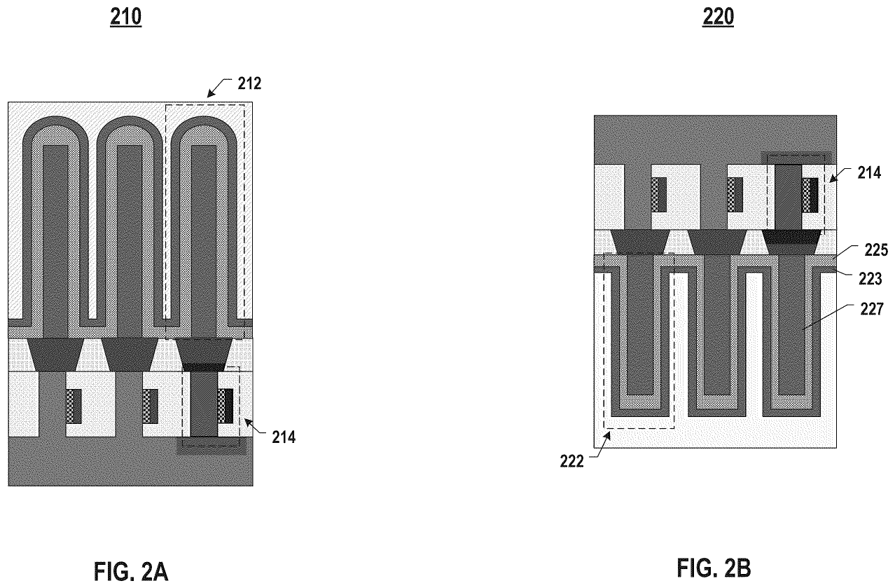

In some implementations, storage unit 134 can be pillar capacitors, as shown in FIG. 2A. Pillar capacitors are provided to achieve higher packing density in a semiconductor device since decreased cell capacitance degrades read-out capability and increases the soft error rate (SER) of the memory cell as well as consumes excessive power during low-voltage operation by impeding device operation.

In some implementations, storage unit 134 in FIG. 1 can be pillar capacitors, as shown in FIG. 2A. Pillar capacitors are provided to achieve higher packing density in a semiconductor device because both outer and inner surfaces of a pillar capacitor can be utilized as an effective capacitor area, the cylindrical structure is favorably suitable for semiconductor device which is 64 Mb or higher. Referring to FIG. 2A, pillar capacitors 212 in first semiconductor structure 210 stack above vertical transistors 214. In the corresponding fabrication process, pillar capacitors 212 are formed after the formation of vertical transistors 214. Besides the difficulty of alignment, vertical transistors 214 are required to survive high-temperature (above 400° C.) processes which are required to form pillar capacitors 212, such as etching and annealing. In these implementations, materials such as metal oxide semiconductors cannot be used in vertical transistors 214 as they cannot afford temperature higher than 300° C. Furthermore, the outer surfaces of pillar capacitors 212 are formed by replacing sacrifice layer using conductors, which make the manufacturing process more complex and costly. Therefore, it is very desirable to develop processes that are as simple as possible and also have large process windows.

FIG. 2B illustrates a cross-section of semiconductor device 220 which includes cup capacitors 222 and vertical transistors formed above cup capacitors 222. Vertical transistors 214 escape from the required high-temperature processes by forming cup capacitors 222 ahead of the formation of vertical transistors 214, therefore metal oxide semiconductors can be applied in semiconductor device 220. Further, as shown in FIG. 2B, cup capacitors 222 includes a first electrode 227, a second electrode 223, and a dielectric layer 225 sandwiched between first electrode 227 and second electrode 223. First electrode 227 of cup capacitors 222 is coupled with vertical transistors 214. Second electrodes 223 of cup capacitors 222 are formed before the formation of dielectric layer 225 of cup capacitors 222 and are connected to a common plate. Therefore, the distance between two adjacent capacitors can be minimized stably without bending risk, and the depth of cup capacitors 222 can be increased without any mask layer. Both manufacturing complexity and cost can be improved by replacing pillar capacitors 212 with cup capacitors 222 as shown in FIG. 2B.

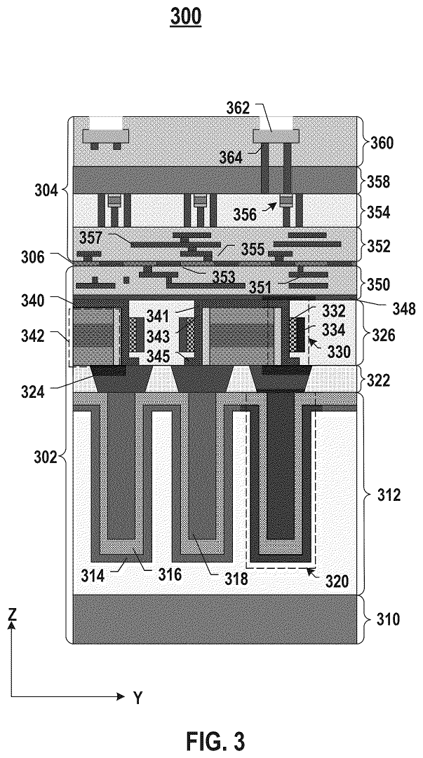

FIG. 3 illustrates a side view of a cross-section of a semiconductor device 300 including vertical transistors, according to some aspects of the present disclosure. It is understood that FIG. 3 is for illustrative purposes only and may not necessarily reflect the actual device structure (e.g., interconnections) in practice. In some implementations, semiconductor device 300 represents an example of a bonded chip. The components of semiconductor device 300 (e.g., memory cell array and peripheral circuits) can be formed separately on different substrates and then joined to form a bonded chip. Semiconductor device 300 can include a first semiconductor structure 302 including the peripheral circuits of a memory cell array. Semiconductor device 300 can also include a second semiconductor structure 304 including the memory cell array stacked above or under first semiconductor structure 302. First and second semiconductor structures 302 and 304 are formed on different substrate and are jointed at bonding interface 306 therebetween, according to some implementations. As shown in FIG. 3, first semiconductor structure 302 can include a substrate 358, and second semiconductor structure can include a substrate 310, substrates 358 and 310 can include silicon (e.g., single crystalline silicon, c-Si), silicon germanium (SiGe), gallium arsenide (GaAs), germanium (Ge), silicon-on-insulator (SOI), or any other suitable materials.

As shown in FIG. 3, second semiconductor structure 304 includes a DRAM device in which memory cells are provided in the form of an array of DRAM cells above substrate 310. DRAM cell can be a 1T1C cell consisting of one transistor and one capacitor. It is understood that DRAM cell may be of any suitable configurations, such as 2TIC cell, 3TIC cell, etc. In some implementations, each DRAM cell includes a cup capacitor 320 and a vertical transistor 330 coupled with the cup capacitor 320. Cup capacitors 320 can be formed on substrate 310 and include a first electrode 314, a second electrode 318, and a dielectric layer 316 formed between first electrode 314 and second electrode 318. First electrode 314 can be formed in a plurality of cell holes of an isolation layer 312 formed on substrate 310. A depth of the cell holes is smaller than a thickness of isolation layer 312. Capacitor 320 can be a vertical capacitor in which first and second electrodes 314 and 318, and dielectric layer 316 are stacked vertically (in the z-direction), and dielectric layer 316 can be sandwiched between first and second electrodes 314 and 318. In some implementations all first electrodes 314 are coupled to the ground through a common plate, while each second electrode 318 is coupled to a source or drain of a respective vertical transistor 330 in the same DRAM cell.

In some implementations, first electrodes 314 and/or the second electrode 318 can include conductive materials including, but not limited to, W, Co, Cu, Al, TiN, TaN, polysilicon, silicide, or any combination thereof. In some implementations, first electrodes 314 and/or the second electrode 318 include a multiple-layer structure, each layer of the multiple-layer structure comprising one of TiN, TaN, carbon, polysilicon, metal, metal compounds, and silicide. In some implementations, dielectric layer 316 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, capacitors 320 may have a relatively large height without any mesh layer as capacitors 320 are formed in cell holes of isolation layer 312 directly, as shown in FIG. 3. Capacitors 320 can keep stable during the fabrication process as no replacement of a sacrifice layer is needed to form capacitors 320.

As shown in FIG. 3, vertical transistor 330 can be a MOSFET used to switch a respective DRAM cell. In some implementations, vertical transistor 330 includes a semiconductor layer 340 (i.e., the active region in which multiple channels can form) extending vertically (in the z-direction), and a gate structure coupled with a plurality of sides of semiconductor layer 340. In some implementations, a leakage value of the semiconductor layer 340 is lower than a pico-ampere, for example, semiconductor layer 340 can include a metal oxide semiconductor material. In present implementation, the semiconductor layer can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 3, in some implementations, semiconductor layer 340 includes a vertical portion 343 extending in a vertical direction (the z-direction), a first lateral portion 341 extending from a first end of vertical portion 343 in a lateral direction (the y-direction), and a second lateral portion 345 extending from a second end of vertical portion 343 in the lateral direction (the y-direction). First lateral portion 341 is coupled with bit line 348, and second lateral portion 345 is coupled with the corresponding capacitor 320. Referring to FIG. 3, two first lateral portions 341 of the semiconductor layers of two adjacent vertical transistors 330 in the lateral direction are connected with each other, that is, semiconductor layers 340 of two adjacent vertical transistors 330 have a U-shaped cross-section in y-z plane.

Vertical transistor 330 can further include a source and a drain disposed at the two ends (the upper end and lower end) of semiconductor layer 340, respectively, in the vertical direction (the z-direction). In some implementations, one of source and drain is coupled to capacitor 320, and the other one of source and drain is coupled to bit line 348. Source and drain can be doped with N-type dopants (e.g., P or As) or P-type dopants (e.g., B or Ga) at a desired doping level. As shown in FIG. 3, in some implementations, source node contacts 324 are formed between second electrode 318 of cup capacitors 320 and source ends of vertical transistors 330. Source node contacts 324 are surrounded by dielectric layer 322 for isolation, and top surfaces of source node contacts 324 are exposed from dielectric layer 322 to couple with vertical transistor 330. In some implementations, top portions of cup capacitors 320 are recessed to accommodate and align with source node contact 324. In some implementations, source node contact may include a heavily doped polysilicon to form an Ohmic contact with source ends of vertical transistors 330 to decrease contact resistance. In some implementations, a contact area between capacitor 320 and vertical transistor 330 equals an area of second lateral portion 345 on the x-y plane, which is tens of times than an area of the second end of vertical portion 343 on the x-y plane, the contact resistance can be further reduced due to the increasement of contact area. As shown in FIG. 3, the source or drain coupled to bit line 348 extends in the lateral direction (the y-direction), bit line 348 may be formed directly on the lateral extending source or drain of vertical transistor 330, fabrication process is simplified compared to coupled bit line 348 with the first end of vertical portion 343.

In some implementations, gate structure includes a gate dielectric 332 and a gate electrode 334. In some implementations, gate dielectric 332 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode 334 includes conductive materials including, but not limited to W, Co, Cu, Al, TiN, TaN, polysilicon, silicide, or any combination thereof. In some implementations, gate electrode 334 includes multiple conductive layers, such as a W layer over a TiN layer. In one example, gate structure may be a “gate oxide/gate poly” gate in which gate dielectric 332 includes silicon oxide and gate electrode includes doped polysilicon. In another example, gate structure may be a high-k metal gate (HKMG) in which gate dielectric 332 includes a high-k dielectric, and gate electrode includes a metal.

As described above, since gate electrode 334 may be part of a word line or extend in the word line direction (the x-direction) as a word line, although not directly shown in FIG. 2, second semiconductor structure 304 of semiconductor device 300 can also include a plurality of word lines, each extending in the word line direction (the x-direction). Each word line can be coupled to a row of DRAM cells. That is, bit line 348 and word line can extend in two perpendicular lateral directions, and semiconductor layer 340 of vertical transistor 330 can extend in the vertical direction perpendicular to the two lateral directions in which bit line 348 and word line extend.

In some implementations, the rows of vertical transistors 330 separated by isolation structure 342 are mirror-symmetric to one another with respect to isolation structure 342, the gate structure of vertical transistor 330 is positioned in a side of vertical portion 343 of semiconductor layer 340 opposite to isolation structure 342. Isolation structure 342 can be formed with dielectric materials including, but not limited to, silicon oxide, silicon nitride, silicon oxynitride, low-k dielectrics, or any combination thereof. It is understood that isolation structure 342 may include an air gap each disposed laterally between adjacent semiconductor layers 340. As described below with respect to the fabrication process, air gaps may be formed due to the relatively small pitches of vertical transistors 330 in the bit line direction (e.g., the y-direction). On the other hand, the relatively large dielectric constant of air in air gaps (e.g., about 4 times the dielectric constant of silicon oxide) can improve the insulation effect between vertical transistors 330 compared with some dielectrics (e.g., silicon oxide).

In some implementations, isolation structure 342 includes a conductor layer surrounded by a dielectric layer. The plurality of conductor layers in semiconductor device 300 are connected to a common grand so that no charge can be accumulated between two adjacent vertical transistors, in this way, electrical coupling between the semiconductor layers 340 of two adjacent vertical transistor can be greatly reduced. In some implementations, conductor layer includes conductive materials including, but not limited to W, Co, Cu, Al, TiN, TaN, polysilicon, silicide, or any combination thereof. In some implementations, conductor layer includes multiple conductive layers, such as a W layer over a TiN layer. As shown in FIG. 3, the dielectric layer includes a first dielectric layer under conductor layer, a second dielectric layer on conductor layer, a left sidewall on the left of conductor layer to separate the conductor layer from a first vertical transistor on the left, and a right sidewall on the right of conductor layer to separate conductor layer from a second vertical transistor on the right. That is, conductor layer is surrounded by dielectric layer to be isolated from the adjacent semiconductor layers 340. In some implementations, dielectric layer includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, the first dielectric layer, the second dielectric layer, the left sidewall, and the right sidewall include different materials. In some implementations, semiconductor device 300 further includes isolation layer 326 formed between the gate structure of two adjacent vertical transistors, isolation layer 326 functions as inter-layer dielectric (ILD) to separate and isolate adjacent vertical transistors. As shown in FIG. 3, isolation layer 326 is flush with semiconductor layer 340.

In some implementations, second semiconductor structure 304 further includes an interconnect layer 350 including bit lines 348 above bonding layer 353 to transfer electrical signals. Interconnect layer 350 can include a plurality of interconnects (also referred to herein as “contacts”), including lateral interconnect lines and vertical interconnect access (VIA) contacts. In some implementations, the interconnects in interconnect layer 350 also include local interconnects, such as bit line contacts, word line contacts, and capacitor contacts. As used herein, the term “interconnects” can broadly include any suitable types of interconnects, such as middle-end-of-line (MEOL) interconnects and back-end-of-line (BEOL) interconnects. Interconnect layer 350 can further include one or more interlayer dielectric (ILD) layers (also known as “intermetal dielectric (IMD) layers”) in which the interconnect lines and via contacts can form. That is, interconnect layer 350 can include interconnect lines and via contacts in multiple ILD layers. The interconnects in interconnect layer 350 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

Second semiconductor structure 304 can be bonded on top of first semiconductor structure 302 in a face-to-face manner at bonding interface 306. Second semiconductor structure 304 can include peripheral circuits 354 on substrate 358. In some implementations, peripheral circuits 354 includes a plurality of transistors 356 (e.g., planar transistors and/or semiconductor transistors). Trench isolations (e.g., shallow trench isolations (STIs)) and doped regions (e.g., wells, sources, and drains of transistors 356) can be formed on or in substrate 358 as well.

In some implementations, second semiconductor structure 304 further includes an interconnect layer 352 formed between peripheral circuits 354 and interconnect layer 350 to transfer electrical signals to and from peripheral circuits 354. Interconnect layer 352 can include a plurality of interconnects (also referred to herein as “contacts”), including lateral interconnect lines and VIA contacts. Interconnect layer 352 can further include one or more interlayer dielectric ILD layers in which the interconnect lines and via contacts can form. That is, interconnect layer 352 can include interconnect lines and via contacts in multiple ILD layers. In some implementations, peripheral circuits 354 are coupled to one another through the interconnects in interconnect layer 352. The interconnects in interconnect layer 352 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 3, second semiconductor structure 304 can further include a bonding layer 355 at bonding interface 306 and under interconnect layer 352 and peripheral circuits 354. Bonding layer 355 can include a plurality of bonding contacts 357 and dielectrics electrically isolating bonding contacts 357. Bonding contacts 357 can include conductive materials, such as Cu. The remaining area of bonding layer 355 can be formed with dielectric materials, such as silicon oxide. Bonding contacts 357 and surrounding dielectrics in bonding layer 355 can be used for hybrid bonding. Similarly, as shown in FIG. 3, first semiconductor structure 302 can also include a bonding layer 353 at bonding interface 306 and under bonding layer 355 of first semiconductor structure 302. Bonding layer 353 can include a plurality of bonding contacts 351 and dielectrics electrically isolating bonding contacts 351. Bonding contacts 351 can include conductive materials, such as Cu. The remaining area of bonding layer 353 can be formed with dielectric materials, such as silicon oxide. Bonding contacts 351 and surrounding dielectrics in bonding layer 353 can be used for hybrid bonding. Bonding contacts 351 are coupled with bonding contacts 357 at bonding interface 306, according to some implementations.

In some implementations, bonding interface 306 is disposed between bonding layers 353 and 355 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 306 is the place at which bonding layers 353 and 355 are met and bonded. In practice, bonding interface 306 can be a layer with a certain thickness that includes the top surface of bonding layer 355 of first semiconductor structure 302 and the bottom surface of bonding layer 353 of second semiconductor structure 304.

As shown in FIG. 3, in some implementations, vertical transistors 330 are disposed vertically between capacitors 320 and bonding interface 306. That is, vertical transistors 330 can be arranged closer to peripheral circuits 354 of first semiconductor structure 302 and bonding interface 306 than capacitors 320. Since bit lines 348 and capacitors 320 are coupled to opposite ends of vertical transistors 330, as described above, bit lines 348 (as part of interconnect layer 350) are disposed vertically between vertical transistors 330 and bonding interface 306, according to some implementations. As a result, interconnect layer 350 including bit lines 348 can be arranged close to bonding interface 306 to reduce the interconnect routing distance and complexity.

As shown in FIG. 3, second semiconductor structure 304 can further include a pad-out interconnect layer 360 above peripheral circuit 354. Pad-out interconnect layer 360 can include interconnects, e.g., contact pads 362, in one or more ILD layers. Pad-out interconnect layer 360 and DRAM cells can be formed on opposite sides of bonding interface 306. In some implementations, the interconnects in pad-out interconnect layer 360 can transfer electrical signals between semiconductor device 300 and outside circuits, e.g., for pad-out purposes. In some implementations, second semiconductor structure 304 further includes one or more contacts 364 extending through part of pad-out interconnect layer 360 to couple pad-out interconnect layer 360 to interconnect layer 350. Peripheral circuits 354 can be coupled to DRAM cells through interconnect layers 352 and 350 as well as bonding layers 353 and 355. Peripheral circuits 354 and DRAM cells can be coupled to outside circuits through contacts 3644 and pad-out interconnect layer 360. Contact pads 362 and contacts 364 can include conductive materials including, but not limited to, W, Co, Cu, Al, silicides, or any combination thereof. In one example, contact pad 362 may include Al, and contact 364 may include W. It is understood that the vertical transistors 330 in DRAM cells are not limited to single-gate transistors as shown in FIG. 3 and may be double-gate transistors or gate-all-around transistors, the structure of which will be detailed below.

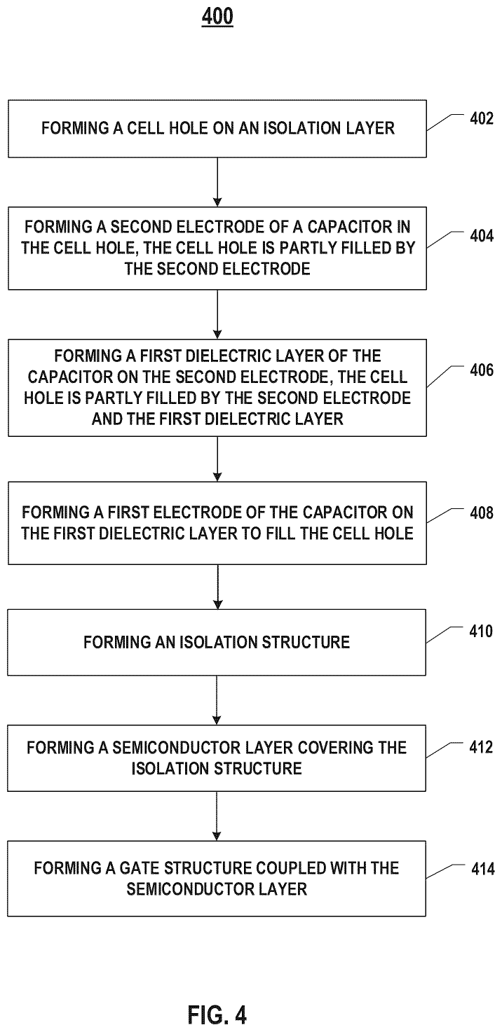

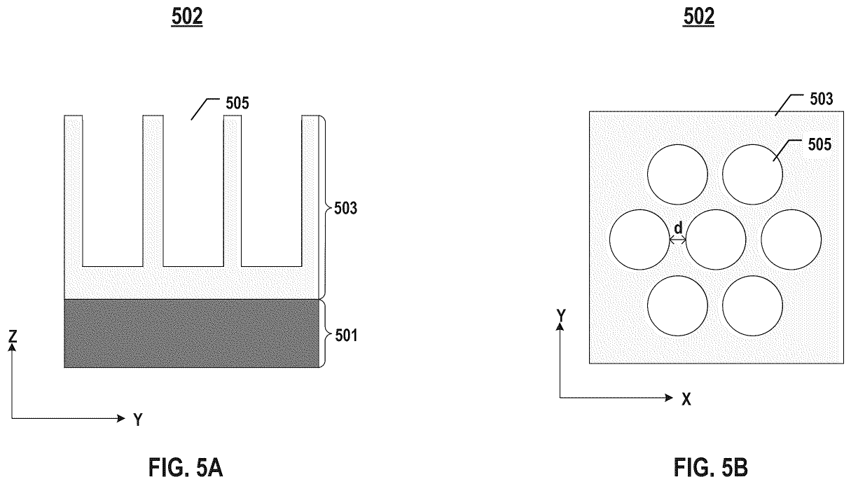

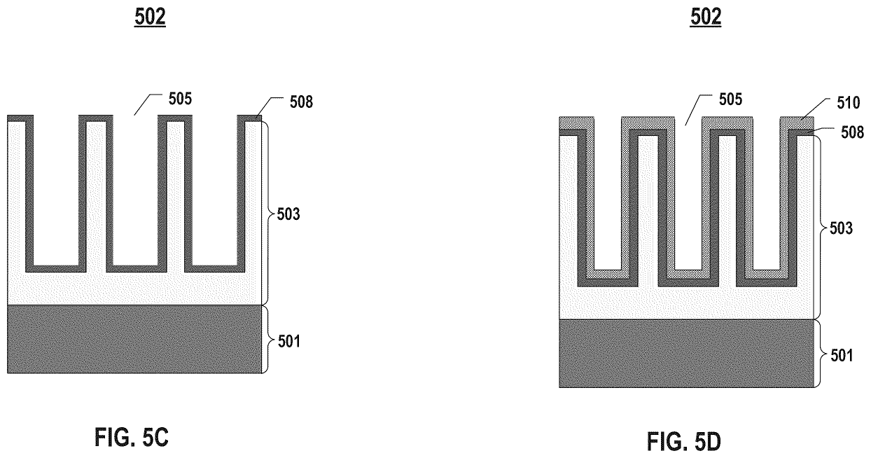

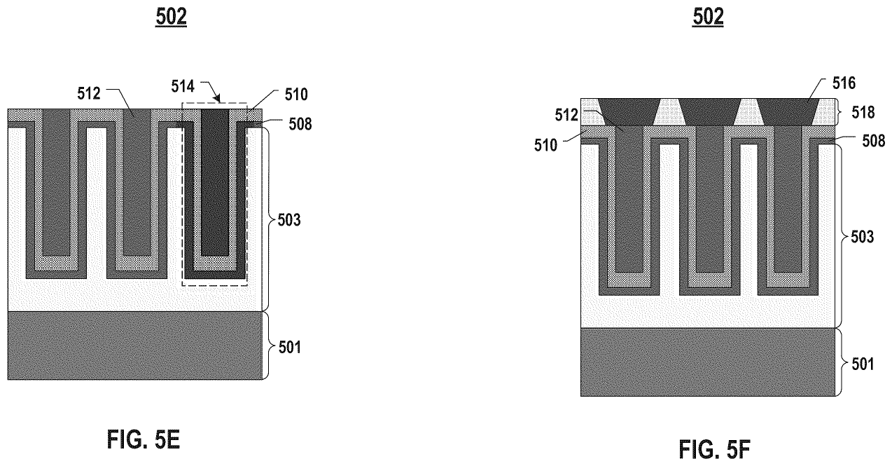

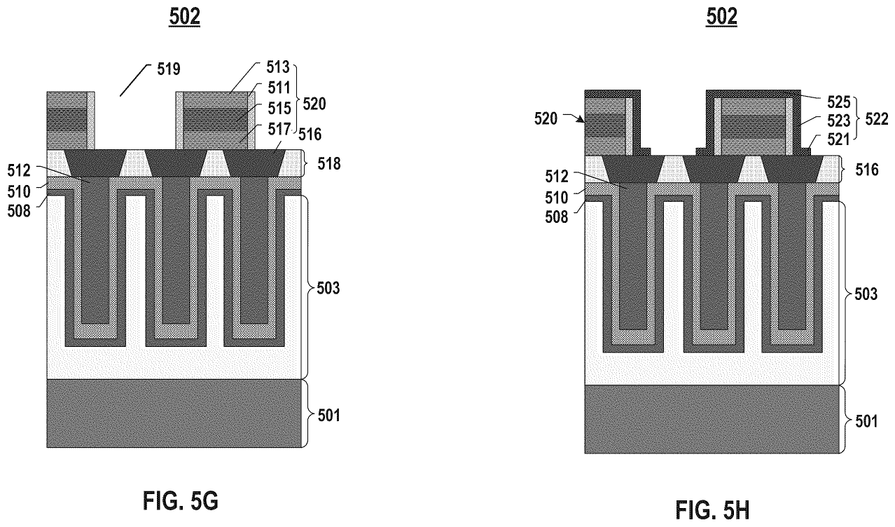

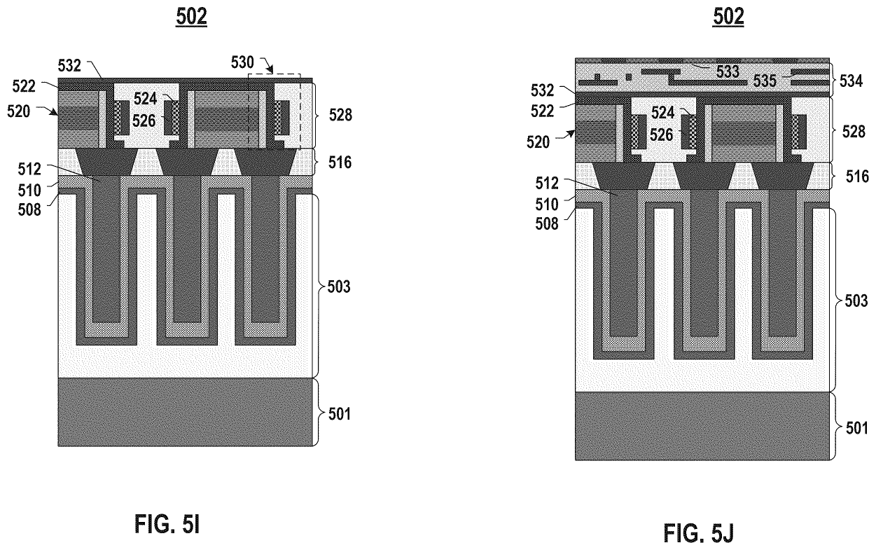

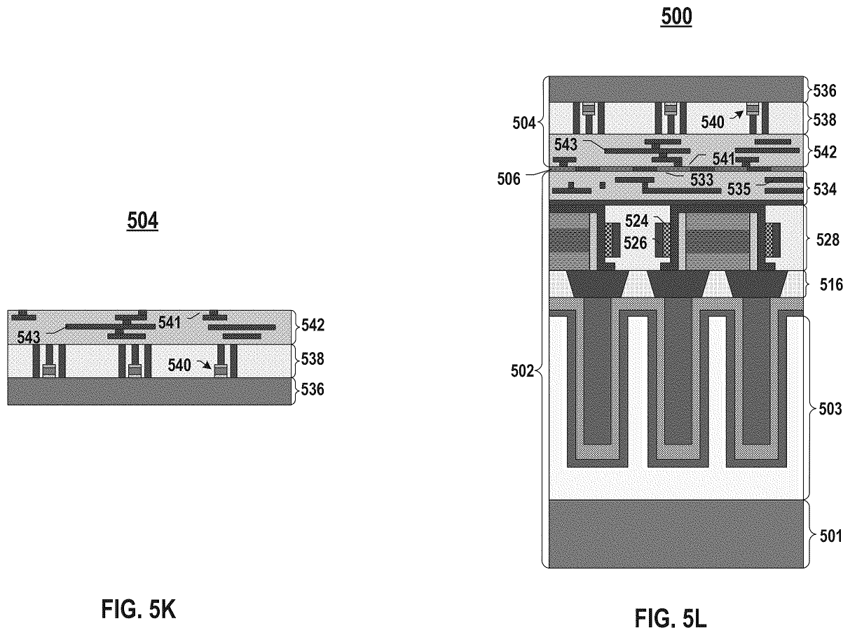

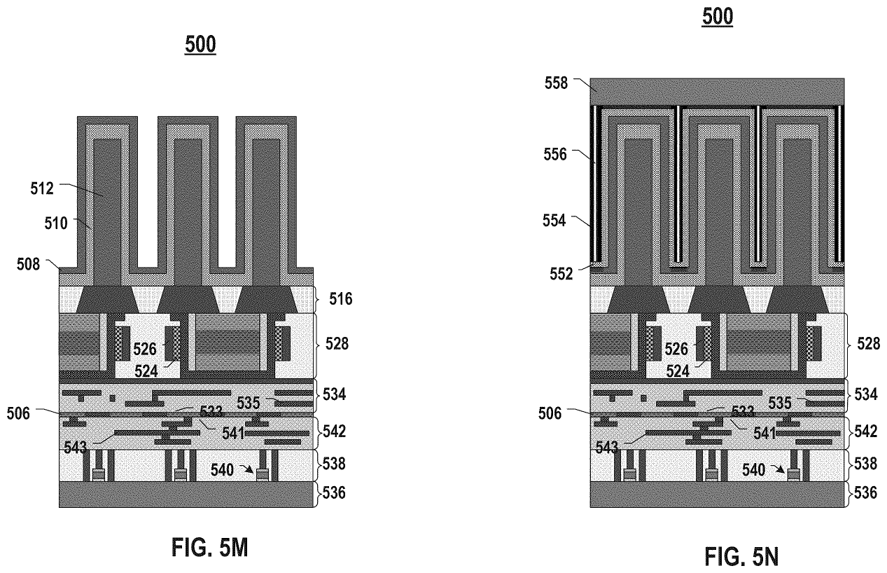

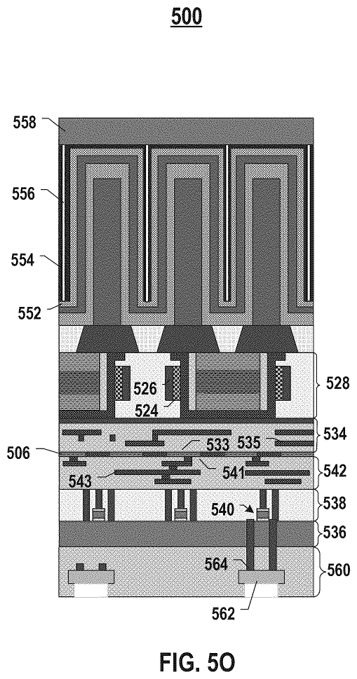

FIG. 4 illustrates a flowchart of a fabricating method 400 for forming a semiconductor device including DRAM cells, according to some implementations of the present disclosure. FIGS. 5A-50 illustrate schematic views of a first semiconductor structure 502 of semiconductor device 500 at certain fabricating stages of the method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4.

As shown in FIG. 4, method 400 can start at operation 402 to form a cell hole 505 on an isolation layer 503. At operation 402, isolation layer 503 can be formed on a substrate 501 of a first semiconductor 502. FIG. 5A illustrates a schematic side cross-sectional view of first semiconductor structure 502 in y-z plane after operation 402 of method 400, FIG. 5B illustrates a schematic top view of first semiconductor structure 502 in x-y plane after operation 402 of method 400.

In some implementations, as shown in FIG. 5A, substrate 501 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In some other implementations, substrate 501 can be a carrier substrate, which can include any suitable semiconductor materials, or an electrically non-conductive material, such as a glass, a plastic, or a sapphire wafer. In some implementations, substrate 501 can be omitted. Isolation layer 503 is formed on substrate 501 to define a region in which capacitors are formed. Isolation layer 503 may be any suitable material that is different from the dielectric layer of capacitors 514. Cell holes 505 may have a large aspect ratio without any mesh layer for support. Cell holes 505 may be arranged in various shapes such as honeycomb, rectangle, diamond, etc. As capacitors 514 are formed in cell holes 505 directly, a minimum distance d between two adjacent cell holes 505 can be minimized to zero, in some implementations.

As shown in FIG. 4, method 400 can proceed to operation 404, in which second electrodes 508 of capacitors 514 are formed in cell holes 505 and cell holes 505 are partly filled by second electrodes 508. FIG. 5C illustrates a schematic side cross-sectional view of first semiconductor structure 502 in y-z plane after operation 404 of method 400. As shown in FIG. 5C, second electrode 508 of each capacitor 514 is part of a conductive layer (referred to as 508 as well) covering cell holes 505 and isolation layer 503. Materials of conductive layer 508 include, but not limited to, W, Co, Cu, Al, TIN, TaN, polysilicon, silicide, or any combination thereof. Second electrode 508 of capacitor 514 may be formed by one or more thin film deposition processes including, but not limited to, chemical vapor deposition (CVD), physical vapor deposition (PVD), atomic layer deposition (ALD), or any combination thereof. As shown in FIG. 5C, second electrodes 508 of capacitors 514 can be connected with each other once being formed, thus they can be coupled to the ground directly without a common plate. Further, the aspect ratio of capacitors 514 would not be limited by the stability requirement for a replacement of a sacrifice layer, which is used to form the second electrode of the pillar capacitor. As no etching or patterning process are required to form second electrodes 508, the fabrication complexity and cost are significantly reduced.

Method 400 can then proceed to operation 406, in which a first dielectric layer 510 of the capacitors 514 is formed to cover second electrode 508 of capacitor 514, and each cell hole 505 is further filled by first dielectric layer 510. FIG. 5D illustrates a schematic side cross-sectional view of first semiconductor structure 502 in y-z plane after operation 406 of method 400. As shown in FIG. 5D, in some implementations, first dielectric layer 510 includes dielectric materials, such as silicon oxide, silicon nitride, or high-k dielectrics including, but not limited to, Al₂O₃, HfO₂, Ta₂O₅, ZrO₂, TiO₂, or any combination thereof. It should be noted that dielectric layer 510 has a different material from isolation layer 503. First dielectric layer 510 of capacitor 514 may be formed by one or more thin film deposition processes including, but not limited to, CVD, PVD, ALD, or any combination thereof.

As shown in FIG. 4, method 400 can proceed to operation 408, in which a first electrode 512 of the capacitor 514 is formed on first dielectric layer 510. FIG. 5E illustrates a schematic side cross-sectional view of first semiconductor structure 502 in y-z plane after operation 408 of method 400. As shown in FIG. 5E, cell holes 505 are fully filled by second electrodes 508, first dielectric layer 510, and first electrode 512. In some implementations, first electrode 512 can include conductive materials including, but not limited to, W, Co, Cu, Al, TiN, TaN, polysilicon, silicide, or any combination thereof. In some implementations, first electrode 512 may be formed by one or more thin film deposition processes including, but not limited to, CVD, PVD, ALD, or any combination thereof. In some implementations, patterning processes (e.g., photoetching, dry etching, wet etching, cleaning, chemical mechanical polishing (CMP), etc.) are needed to separate and isolate first electrodes 512 of capacitors 514, and a top of first electrodes 512 is flush with first dielectric layer 510, as shown in FIG. 5E.

In some implementations, source node contacts (SNCs) 516 are formed on the top of each first electrode 512, as shown in FIG. 5F. First electrode 512 is made of conductive materials while a source or drain end of vertical transistor 530 is made of semiconductor materials, therefore SNC 516 functions as a transition between first electrode 512 and the source or drain end of vertical transistor 530 to reduce contact resistance between capacitors 514 and vertical transistors 530. SNC 516 may include several layers, for example, a polysilicon layer directly coupled with vertical transistor 530, a metal layer directly coupled with capacitor 514, and a metal oxide layer sandwiched between them. In some implementations, SNC 516 may be formed by one or more thin film deposition processes (e.g., CVD, PVD, ALD, or any combination thereof) and patterning processes (e.g., photoetching, dry etching, wet etching, cleaning, CMP). In some implementations, the top of first electrode 512 is recessed to accommodate SNC 516 and ease alignment. In some implementations, the source or drain end of vertical transistor 530 is heavily doped, SNC 516 may be omitted as an Ohmic contact would be formed between capacitors 514 and vertical transistors 530. Further, an isolation layer 518 is formed to separate and isolate SNC 516, as shown in FIG. 5F, isolation layer 518 is flush with SNC 516.

As shown in FIG. 4, method 400 can proceed to operation 410, in which an isolation structure 520 is formed on isolation layer 518. FIG. 5G illustrates a schematic side cross-sectional view of first semiconductor structure 502 in y-z plane after operation 410 of method 400.

In some implementations, a multiple-layer structure including a conductor layer is formed on the array of capacitors 514 to form an isolation structure 520 between two adjacent transistors, as shown in FIG. 5G. In some implementations, multiple-layer structure includes a first dielectric layer 517, a conductor layer 515 covering first dielectric layer 517, and a second dielectric layer 513 covering the conductor layer 515. In some implementations, first dielectric layer 517 and second dielectric layer 513 can includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, conductor layer 515 can include conductive materials including, but not limited to, W, Co, Cu, Al, TiN, TaN, polysilicon, silicide, or any combination thereof. First dielectric layer 517, conductor layer 515, and second dielectric layer 513 can be formed by a series of fabricating processes including thin film deposition processes (e.g., CVD, PVD, ALD, or any combination thereof) and patterning processes (e.g., photoetching, dry etching, wet etching, cleaning, CMP).

In some implementations, a plurality of isolation trenches 519 are then formed on the multiple-layer structure to separate the multiple layer structure into a plurality of isolation structures 520, as shown in FIG. 5G. Isolation trenches 519 penetrate the multiple-layer structure to expose top ends of capacitors 514. Referring to FIG. 4D, two adjacent capacitors 514 are exposed through the same isolation trench. In some implementations, each isolation trench is configured to expose one corresponding capacitor 514 (not shown in figure). In some implementations, two sidewalls 511 are formed to cover a left side and a right side of each isolation structure 520. In some implementations, the first dielectric layer 517, the second dielectric layer 513, and the sidewalls 511 can include different materials such as silicon oxide, silicon nitride, or high-k dielectrics including, but not limited to, Al₂O₃, HfO₂, Ta₂O₅, ZrO₂, TiO₂, or any combination thereof. In such implementations, conductor layer 515 can be surrounded by dielectric layers all around to be isolated from adjacent vertical transistors. The plurality of conductor layers 515 are connected to a common grand so that no charge can be accumulated between two adjacent vertical transistors, in this way, electrical coupling between semiconductor layers of two adjacent vertical transistor can be greatly reduced. In some implementations, conductor layer 515 includes conductive materials including, but not limited to W, Co, Cu, Al, TiN, TaN, polysilicon, silicide, or any combination thereof. In some implementations, conductor layer 515 includes multiple conductive layers, such as a W layer over a TiN layer.

In some implementations, a semiconductor layer 522 is formed on the isolation structure 520, as shown in FIG. 4E. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc. In some implementations, semiconductor layer 522 can be formed from a deposition process. For example, a semiconductor layer can be formed on covering both isolation structures 520 and isolation trenches 519 by a deposition process, then a portion of the semiconductor layer covering a bottom of isolation trenches 519 can be removed through photolithography to form the plurality of semiconductor layer 522 covering the isolation trenches. In some implementations, semiconductor layer covering capacitors 514 are remained during photolithography to form an extending portion of semiconductor layer 522. As shown in FIG. 4E, semiconductor layer 522 is isolated from conductor layer 515 by first dielectric layer 517, second dielectric layer 513, and sidewalls 511 between conductor layer 515 and semiconductor layer 522.

As shown in FIG. 4, method 400 can proceed to operation 412, in which a semiconductor layer covering isolation structure 520 is formed. FIG. 5H illustrates a schematic side cross-sectional view of first semiconductor structure 502 in y-z plane after operation 412 of method 400.

Referring to FIG. 5H, semiconductor layer 522 of each vertical transistors 530 includes a vertical portion 523 extending in a vertical direction (z-direction), a first lateral portion 525 extending from a first end of vertical portion 523 in a lateral direction (y-direction), and a second lateral portion 521 extending from a second end of vertical portion 523 in the lateral direction (y-direction). The second lateral portion 521 is coupled with the corresponding capacitor 514. First lateral portion 525, vertical portion 523, and second lateral portion 521 are formed as a whole during the fabrication process. As shown in FIG. 5H, each semiconductor layer 522 formed on the corresponding isolation trench 520 has a U-shaped cross-section in y-z plane. The U-shaped semiconductor layer 522 includes vertical portion 523 of a first vertical transistor covering the left sidewall 511, first lateral portion 525 of the first vertical transistor covering second dielectric layer 513, vertical portion 523 of a second vertical transistor covering the right sidewall 511, and first lateral portion 525 of the second vertical transistor covering second dielectric layer 513. In some implementations, the U-shaped semiconductor layer 522 further includes second lateral portions 521 of the first and second vertical transistors.

As shown in FIG. 4, method 400 can proceed to operation 414, in which a gate structure coupled with semiconductor layer 522 is formed. FIG. 5I illustrates a schematic side cross-sectional view of first semiconductor structure 502 in y-z plane after operation 414 of method 400.

As shown in FIG. 5I, gate structure includes a gate dielectric layer 524 and a gate electrode 526. Gate dielectric layer 524 can be formed to cover semiconductor layer 522, in the present implementation. Gate dielectric layer 524 can include any suitable dielectric materials, such as silicon oxide, silicon nitride, silicon oxynitride, or high-k dielectrics. For example, gate dielectric layer 524 may include silicon oxide, i.e., gate oxide, which can be formed during the fabricating of gate electrode 526. In some implementations, gate dielectric layer 524 can be high-k dielectrics including, but not limited to, A1₂O₃, HfO₂, Ta₂O₅, ZrO₂, TiO₂, or any combination thereof. Gate electrode 526 can be formed to cover gate dielectric layer 524. Gate electrode 526 can include any suitable conductive materials, such as polysilicon, metals (e.g., W, Cu, Al, etc.), metal compounds (e.g., TiN, TaN, etc.), or silicide. For example, gate electrode 526 may include doped polysilicon, i.e., a gate poly. In some implementations, gate electrode 526 includes multiple conductive layers, such as a W layer over a TiN layer. An isolation layer 528 is then formed to fill the space between the vertical transistors 530 as shown in FIG. 5I. As described below with respect to the fabrication process, air gaps may be formed in isolation layer 528 between adjacent vertical transistors (not shown in figures). The relatively large dielectric constant of air in the air gap can improve the insulation effect between vertical transistors 530 compared with some dielectrics (e.g., silicon oxide).

In some implementations, referring to FIG. 5I, a plurality of bit lines 532 and word lines 526 (referred to as gate electrodes 526 as well) can be formed on the array of vertical transistors 530. Vertical transistor 530 extends vertically through and is coupled with a corresponding word line 526, and first lateral portion 525 of semiconductor layer 522 of vertical transistor 530 is coupled with bit line 532. As shown in FIG. 5I, bit lines 532 can be formed directly on isolation layer 528 and first lateral portion 525 of semiconductor layer 522 of vertical transistor 530. Compared with bit lines coupled with vertical portion 523, bit lines 532 in the present disclosure can be formed through a deposition process without etching isolation layer 528, and the fabricating difficulty and cost can be greatly reduced.

Referring to FIGS. 5J to 5L, first semiconductor structure 502 is bonded with a second semiconductor structure 504 having a peripheral circuit to form semiconductor device 500 through hypoid bonding. In some implementations, as shown in FIG. 5J, first semiconductor structure 502 can also include an interconnect layer 534 including a bonding layer 533 at bonding interface 506 to be coupled to a bonding layer of a first semiconductor structure 502. Bonding layer 533 can include a plurality of bonding contacts 535 and dielectrics electrically isolating bonding contacts 535. Bonding contacts 535 can include conductive materials, such as Cu. The remaining area of bonding layer 533 can be formed with dielectric materials, such as silicon oxide. Bonding contacts 535 and surrounding dielectrics in bonding layer 533 can be used for hybrid bonding. Bonding contacts 535 may be coupled with bonding contacts of second semiconductor structure 504 at bonding interface 506, according to some implementations.

As shown in FIG. 5K, second semiconductor structure 504 can include peripheral circuits 538 on substrate 536. In some implementations, peripheral circuits 538 includes a plurality of transistors 540 (e.g., planar transistors and/or semiconductor transistors). Trench isolations (e.g., shallow trench isolations (STIs)) and doped regions can be formed on or in substrate 536 as well. In some implementations, second semiconductor structure 504 further includes an interconnect layer 542 above peripheral circuits 538 to transfer electrical signals to and from peripheral circuits 538. Interconnect layer 542 can include interconnect lines and via contacts in multiple ILD layers. In some implementations, peripheral circuits 538 are coupled to one another through the interconnects in interconnect layer 542. The interconnects in interconnect layer 542 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 5K and FIG. 5L, second semiconductor structure 504 can further include a bonding layer 541 at bonding interface 506 and above interconnect layer 542 and peripheral circuits 538. Bonding layer 541 can include a plurality of bonding contacts 543 and dielectrics electrically isolating bonding contacts 543. Bonding contacts 543 can include conductive materials, such as Cu. The remaining area of bonding layer 541 can be formed with dielectric materials, such as silicon oxide. Bonding contacts 543 and surrounding dielectrics in bonding layer 541 can be used for hybrid bonding.

In some implementations, the minimal distance d between two adjacent capacitors is close to or larger than one tenth of the diameter of cell hole 505, thus the isolation layers between two adjacent capacitors can be replaced by a multiple-layer structure to improve the performance of capacitors 514. Referring to FIG. 5M, substrate 501 and isolation layer 503 are removed to expose second electrodes 508 after first semiconductor structure 502 being bonded with second semiconductor structure 504. For example, substrate 501 and isolation layer 503 can be removed through at least one etching process such as dry etching or wet etching. In some implementations, the multiple-layer structure is formed by different conductive layers including TiN, TaN, carbon, polysilicon, metal, metal compounds, and silicide. In some implementations, the material of each layer of the multiple-layer structure is different from the material of other layers.

In some implementations, as shown in FIG. 5N, the multiple-layer structure includes a second dielectric layer 552 formed on the exposed second electrode 508 and a third electrode 554 covering second dielectric layer 552. Second dielectric layer 552 includes dielectric materials, such as silicon oxide, silicon nitride, or high-k dielectrics including, but not limited to, Al₂O₃, HfO₂, Ta₂O₅, ZrO₂, TiO₂, or any combination thereof. Third electrode 554 includes conductive materials, such as TiN, TaN, carbon, polysilicon, metal, metal compounds, silicide, or any combination thereof. In some implementations, second dielectric layer 552 and third electrode 554 can be formed by a series of fabricating processes including thin film deposition processes and patterning processes. In some implementations, a plurality of insolation trenches 556 are formed along the vertical direction to separate and isolated third electrodes 554. Insolation trenches 556 may be formed with third electrode 554 in a same patterning process, or insolation trenches 556 may be formed after third electrode 554 is formed. In some implementations, third electrodes 554 are coupled to a corresponding first electrode 512 respectively, in this way, an effective area of capacitor 514 is doubled with the formation of third electrode 554 without increasing the height of capacitor 514. In some implementations, an isolation layer 558 is formed on third electrode 554 to isolate and protect third electrode 554.

In some implementations, a pad-out interconnect layer 560 is formed, as shown in FIG. 5O, which illustrates a schematic side cross-sectional view of semiconductor device 500 in the y-z plane after pad-out interconnect layer 560 is formed on second semiconductor structure 504. Pad-out interconnect layer 560 can include interconnects, e.g., contact pads 562, in one or more ILD layers. In some implementations, the interconnects in pad-out interconnect layer 560 can transfer electrical signals between the semiconductor device and outside circuits, e.g., for pad-out purposes. In some implementations, pad-out interconnect layer 560 further includes one or more contacts 564 to couple peripheral circuit 538 to DRAM cells. Contact pads 562 and contacts 564 can include conductive materials including, but not limited to, W, Co, Cu, Al, silicide, or any combination thereof. In one example, contact pad 562 may include Al, and contact 564 may include W.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor device, comprising:
vertical transistors each comprising a semiconductor layer and a gate structure coupled to the semiconductor layer; and
cup-shaped capacitors coupled with the vertical transistors correspondingly;
wherein the semiconductor layer of each vertical transistor comprises:
a vertical portion extending in a vertical direction, and
a first lateral portion extending from a first end of the vertical portion in a lateral direction, the first lateral portions of the semiconductor layers of two adjacent vertical transistors in the lateral direction are connected with each other.

2. The semiconductor device of claim 1, wherein
the two adjacent vertical transistors in the lateral direction are separated by an isolation structure; and
the vertical portion of each semiconductor layer is positioned between the isolation structure and the gate structure.

3. The semiconductor device of claim 1, wherein
each cup-shaped capacitor comprises a first electrode, a second electrode, and a first dielectric layer between the first electrode and the second electrode, and the first electrode is directly coupled with the semiconductor layer of the corresponding vertical transistor.

4. The semiconductor device of claim 3, wherein
the second electrode comprises a multiple-layer structure, each layer of the multiple-layer structure comprising one of TiN, TaN, carbon, polysilicon, metal, metal compounds, and silicide.

5. The semiconductor device of claim 3, wherein
the cup-shaped capacitor further comprises a second dielectric layer surrounding the second electrode and third electrode surrounding the second dielectric layer.

6. The semiconductor device of claim 5, wherein
a material of the second dielectric layer is different from a material of the first dielectric layer.

7. The semiconductor device of claim 6, wherein
the material of the second dielectric layer comprises one or a combination of silicon oxide, silicon nitride, silicon oxynitride, or high-k dielectrics.

8. The semiconductor device of claim 3, wherein
the first electrode is directly coupled with a second end of the vertical portion of the semiconductor layer of the corresponding vertical transistor.

9. The semiconductor device of claim 3, wherein
the first electrode is coupled with the semiconductor layer of the corresponding vertical transistor through a contact, and an end of the second electrode coupled with the contact is recessed to accommodate the contact.

10. The semiconductor device of claim 1, wherein
the semiconductor layer having a leakage value lower than a pico-ampere.

11. A method for forming a semiconductor device, comprising:
forming a cup-shaped capacitor comprising:
forming a cell hole on a dielectric substrate;
forming a second electrode of a capacitor in the cell hole, the cell hole is partly filled by the second electrode;
forming a first dielectric layer of the capacitor on the second electrode, the cell hole is partly filled by the second electrode and the first dielectric layer; and
forming a first electrode of the capacitor on the first dielectric layer to fill the cell hole; and
forming a vertical transistor coupled with the second electrode of the cup-shaped capacitor.

12. The method of claim 11, wherein forming the cup-shaped capacitor further comprises:
removing the dielectric substrate to expose the second electrode.

13. The method of claim 12, wherein forming the cup-shaped capacitor further comprises:
forming a second dielectric layer on the second electrode; and
forming a third electrode on the second dielectric layer.

14. The method of claim 13, wherein
a material of the second dielectric layer is different from a material of the first dielectric layer.

15. The method of claim 11, forming a vertical transistor coupled with the second electrode of the cup-shaped capacitor comprising:
forming an isolation structure;
forming a semiconductor layer covering the isolation structure; and
forming a gate structure coupled with the semiconductor layer;
wherein the semiconductor layers of two adjacent vertical transistors have a U-shaped cross-section in a plane formed by a vertical direction and a lateral direction.

16. The method of claim 15, wherein the semiconductor layer comprises:
a vertical portion of a first vertical transistor extending in the vertical direction;
a first lateral portion of the first vertical transistor extending from a first end of the vertical portion of the first vertical transistor in the lateral direction;
a vertical portion of a second vertical transistor extending in the vertical direction; and
a first lateral portion of the second vertical transistor extending from a first end of the vertical portion of the second vertical transistor in the lateral direction.

17. The method of claim 15, before forming the vertical transistor coupled with the cup-shaped capacitor, further comprising:
forming a contact between the first electrode of the capacitor and the semiconductor layer of the corresponding vertical transistor.

18. The method of claim 17, wherein forming the vertical transistor coupled with the cup-shaped capacitor comprises:
etching the first electrode to form a recess to accommodate the contact.

19. The method of claim 15, wherein
the semiconductor layer has a leakage value lower than a pico-ampere.

20. A semiconductor device, comprising:
single-gate vertical transistors; and
storage units coupled with the single-gate vertical transistors correspondingly, wherein
two adjacent single-gate vertical transistors in a lateral direction are separated by an isolation structure and share a U-shaped semiconductor layer covering both sides of the isolation structure in the lateral direction;
a gate structure of the single-gate vertical transistor is coupled with a side of the U-shaped semiconductor layer opposite to the isolation structure; and
each storage unit comprises a cup-shaped capacitor.
